(19) United States
(12) Patent Application Publication
(10) Pub. No.: US 2008/0057693 A1
(43) Pub. Date: Mar. 6, 2008

(54) Electrical conductivity bridge in a conductive multilayer article

(75) Inventors: Darold Dean Tippey, Neenah, WI (US); Thomas Michael Ales, Neenah, WI (US); Thomas David Ehlert, Neenah, WI (US)

Correspondence Address: KIMBERLY-CLARK WORLDWIDE, INC.;Catherine E. Wolf, 401 NORTH LAKE STREET, NEENAH, WI, 54956, US

(73) Assignee: Kimberly-Clark Worldwide, Inc.

(21) Appl. No.: 11/514,541

(22) Filed: Aug. 31, 2006

(51) Int. Cl. H01L 21/44

(52) U.S. Cl. 438/597

(57) ABSTRACT

A method comprises providing a first electrically-conductive circuit-path (22), and separately providing a second electrically-conductive circuit-path (24). A portion of the first circuit-path is positioned proximally adjacent a portion of the second circuit-path at a first predetermined electrical bond location (26). A first, electrically-insulating barrier layer (28) is interposed between the first circuit-path and second circuit-path at the first bond location, and the first circuit-path is mechanically bonded to the second circuit-path at the first bond location. The mechanical bonding configured to provide an electrically-conductive bond-path between the first circuit-path and the second circuit-path at the first bond location. The mechanical bonding may desirably include ultrasonic bonding and/or pressure bonding.

### FIELD OF THE INVENTION

The present invention relates to a method for interconnecting electrical circuits. More particularly, the present invention pertains to a technique for interconnecting electrical circuits through the thickness of an electrically insulating layer.

### BACKGROUND OF THE INVENTION

Electrical circuits have been printed or otherwise applied to flexible substrates, such as paper, woven fabrics, nonwoven fabrics and polymer films. The electrical circuits have incorporated electrically-conductive inks applied with conventional ink-printing techniques and various products, such as badges, labels and tags, have incorporated the printed circuits. In particular arrangements, the printed circuits have been employed in hygienic products, such as drapes, gowns, garments, personal care absorbent products, and the like. In other arrangements, electrical/electronic circuitry has been employed to provide sensors located in selected personal care products, such as wetness sensors located in disposable infant diapers.

Conventional ink-printed circuit configurations, however, have included a printing of conductive ink on one side of a single layer of a polymer film or other flexible substrate composed of electrically-insulating material. Ink-printed circuits positioned on a single side of an insulating substrate can present problems when attempting to connect the printed circuit to a cooperating sensor or other external electrical monitoring device that is positioned on an opposite side of the insulating substrate. Interconnecting, conductive pathways formed through the thickness of the insulating substrate have excessively compromised the desired properties of the substrate. For example, where the substrate is desired to be substantially liquid-impermeable, the formation of the conductive pathway through the thickness of the insulating substrate has excessively degraded the desired level of liquid-impermeability. As a result, when the liquid-impermeable substrate and cooperating monitoring device have been employed on a garment, it has been necessary to position the interconnecting, conductive pathway at a garment location that can cause excessive irritation to a wearer of the garment. In addition, it has been difficult to form a strong and reliable electrical and mechanical interconnection that can sufficiently resist failure due to mechanical stress-fatigue generated by movements of the substrate material during the wearer's activities.

### BRIEF DESCRIPTION OF THE INVENTION

Generally stated, the present invention provides a distinctive process and method which includes providing a first electrically-conductive circuit-path, and separately providing a second electrically-conductive circuit-path. A portion of the first circuit-path is positioned proximally adjacent a portion of the second circuit-path at a first predetermined bond location. A first, electrically-insulating barrier layer is interposed between the first circuit-path and second circuit-path at the first bond location, and the first circuit-path is mechanically bonded to the second circuit-path at the first bond location. The mechanical bonding is configured to provide an electrically-conductive bond-path between the first circuit-path and the second circuit-path at the first bond location. In a particular aspect, the mechanical bonding can include ultrasonic bonding. Another aspect can have the first electrically-conductive circuit-path operatively connected to a sensor mechanism which provides sensor data. In a further aspect, the second electrically-conductive circuit-path can be operatively connected to an electronic processor mechanism which receives the sensor data and provides selected signal data.

By incorporating its various aspects and features, the method can provide a desired, electrically-conductive interconnecting pathway between electrically-conductive circuit-paths that are positioned on opposite sides of an electrically-insulating substrate. The interconnecting conductive pathway can penetrate and extend through the thickness dimension of the substrate, and the formation of the interconnecting conductive pathway can be configured to operatively maintain desired properties of the substrate. For example, the formation of the interconnecting conductive pathway can be configured to operatively maintain a desired liquid-impermeable, barrier property of the substrate. As a result, the interconnecting conductive pathway can be positioned at a greater range of locations and can help provide greater versatility. For example, when the conductive pathway interconnects a circuit-path that is positioned on one side of the insulating substrate to a cooperating sensor or other external electrical monitoring device that is positioned on an opposite side of the substrate, the conductive pathway can have a location that allows a cooperative positioning of the monitoring device at a location that provides improved comfort to the wearer. In an additional aspect, the formation of the interconnecting conductive pathway can be configured to provide a desired level of mechanical bonding strength between selected components. As a result, the formation of the interconnecting conductive pathway can be configured to provide improved reliability. Where the first electrically conductive circuit-path has been applied to a first substrate, and the second electrically conductive circuit-path has been applied to a second substrate, the mechanical bonding can be configured to supplement the mechanical strength of the interconnecting pathway. For example, a portion of the first substrate can be bonded to a portion of the second substrate to increase the total mechanical strength of the bonded, interconnecting, conductive pathway. The higher mechanical strengths can help reduce electrical failures of the conductive pathway caused by a mechanical fatigue of the interconnecting conductive pathway arising from stresses generated by movements of a user. Additionally, more complex arrays of circuit-paths can be produced with fewer layers of substrate material. The reduced layers of substrate material can help reduce the thickness of the overall end-product, and can help increase the flexibility of the desired end-product.

### BRIEF DESCRIPTION OF THE DRAWINGS

The invention will be better understood by reference to the following description of the invention taken in conjunction with the accompanying drawings, wherein:

FIG. 1 shows a top plan view of a representative, barrier layer substrate in which a first circuit-path is located on a first, major facing-surface of the substrate and is connected to a second circuit-path located on an opposite, second, major facing-surface of the substrate with an electrically-conductive bond-path.

FIG. 1A shows a representative cross-sectional view of a substrate and associated circuit-paths taken along section 1A-1A of FIG. 1.

FIG. 2 shows a top plan view of a representative arrangement wherein a first circuit-path is located on a first substrate; a second circuit-path is located on a second substrate; a third circuit-path is located on a third substrate; the first circuit-path is connected to the second circuit-path along a first electrically-conductive bond-path through the thickness of the second substrate; and the second circuit-path is connected to the third circuit-path along a second electrically-conductive bond-path through the thickness of the third substrate.

FIG. 3 shows a representative, schematic arrangement for determining the resistance of an electrically-conductive bond-path.

FIG. 4 shows a partially cut-away, perspective view of a representative article having a sensor or other external electrical monitoring device that is positioned on an inward side surface of the insulating substrate and interconnects along a conductive pathway through the substrate to a circuit-path and cooperating processor that is positioned on an opposite, outward side of the substrate.

FIG. 5 shows a perspective, partial view of another representative arrangement of a first-circuit path that is positioned on a conductive bond-path through the substrate to a second circuit-path and cooperating processor that is positioned on an opposite, outward-side surface of the substrate.

### DETAILED DESCRIPTION OF THE INVENTION

It should be noted that, when employed in the present disclosure, the terms “comprises”, “comprising” and other derivatives from the root term “comprise” are intended to be open-ended terms that specify the presence of any stated features, elements, integers, steps, or components, and are not intended to preclude the presence or addition of one or more other features, elements, integers, steps, components, or groups thereof.

By the terms “particle,” “particles,” “particulate,” “particulates” and the like, it is meant that the material is generally in the form of discrete units. The units can comprise granules, powders, spheres, pulverized materials or the like, as well as combinations thereof. The particles can have any desired shape such as, for example, cubic, rod-like, polyhedral, spherical or semi-spherical, rounded or semi-rounded, angular, irregular, etc. Shapes having a large greatest dimension/smallest dimension ratio, like needles, flakes and fibers, are also contemplated for inclusion herein. The terms “particle” or “particulate” may also include an agglomeration comprising more than one individual particle, particulate or the like. Additionally, a particle, particulate or any desired agglomeration thereof may be composed of more than one type of material.

As used herein, the term “nonwoven” refers to a fabric web that has a structure of individual fibers or filaments which are interlaid, but not in an identifiable repeating manner.

As used herein, the terms “spunbond” or “spunbonded fiber” refer to fibers which are formed by extruding filaments of molten thermoplastic material from a plurality of fine, usually circular, capillaries of a spinneret, and then rapidly reducing the diameter of the extruded filaments.

As used herein, the phrase “meltblown fibers” refers to fibers formed by extruding a molten thermoplastic material through a plurality of fine, usually circular, die capillaries as molten threads or filaments into a high velocity, usually heated, gas (e.g., air) stream which attenuates the filaments of molten thermoplastic material to reduce their diameter. Thereafter, the meltblown fibers are carried by the high velocity gas stream and are deposited on a collecting surface to form a web of randomly disbursed meltblown fibers.

“Coform” as used herein is intended to describe a blend of meltblown fibers and cellulose fibers that is formed by air forming a meltblown polymer material while simultaneously blowing air-suspended cellulose fibers into the stream of meltblown fibers. The meltblown fibers containing wood fibers are collected on a forming surface, such as provided by a foraminous belt. The forming surface may include a gas-pervious material, such as spunbonded fabric material, that has been placed onto the forming surface.

As used herein, the phrase “absorbent article” refers to devices which absorb and contain body liquids, and more specifically, refers to devices which are placed against or near the skin to absorb and contain the various liquids discharged from the body. The term “disposable” is used herein to describe absorbent articles that are not intended to be laundered or otherwise restored or reused as an absorbent article after a single use. Examples of such disposable absorbent articles include, but are not limited to: health care related products including surgical drapes, gowns, and sterile wraps; personal care absorbent products such as feminine hygiene products (e.g., sanitary napkins, pantiliners, tampons, interlabial devices and the like), infant diapers, children's training pants, adult incontinence products and the like; as well as absorbent wipes and covering mats.

Disposable absorbent articles such as, for example, many of the personal care absorbent products, can include a liquid pervious topsheet, a substantially liquid impervious backsheet joined to the topsheet, and an absorbent core positioned and held between the topsheet and the backsheet. The topsheet is operatively permeable to the liquids that are intended to be held or stored by the absorbent article, and the backsheet may be substantially impermeable or otherwise operatively impermeable to the intended liquids. The absorbent article may also include other components, such as liquid wicking layers, liquid distribution layers, barrier layers, and the like, as well as combinations thereof. Disposable absorbent articles and the components thereof, can operate to provide a body-facing surface and a garment-facing surface. As used herein, “body-facing surface” means that surface of the article or component which is intended to be disposed toward or placed adjacent to the body of the wearer during ordinary use, while the “outward surface” or “outward-facing surface” is on the opposite side, and is intended to be disposed to face away from the wearer's body during ordinary use. The outward surface may be arranged to face toward or placed adjacent to the wearer's undergarments when the absorbent article is worn.

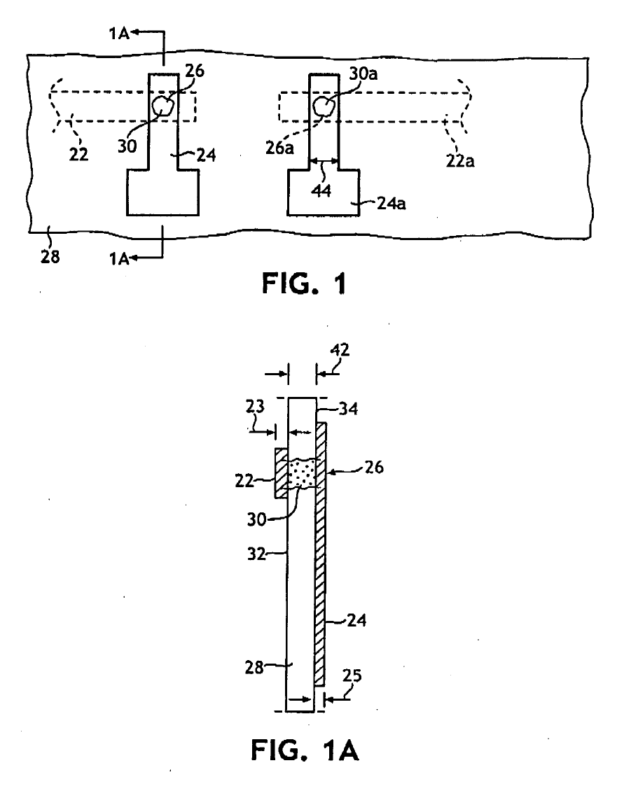

With reference to FIGS. 1 through 5, a distinctive method for forming an operative, electrically-conductive path through the thickness of an electrical barrier layer can comprise providing a first, electrically conductive circuit-path 22; and separately providing a second, electrically conductive circuit-path 24. A portion of the first circuit-path can be positioned proximally adjacent a portion of the second circuit-path at a first predetermined, electrically-conductive bond location 26, and a first, electrically-insulating barrier layer 28 can be operatively provided in a configuration which is interposed between the first circuit-path and the second circuit-path at the first bond location. The first circuit-path 22 has been mechanically bonded to the second circuit-path 24 at the first bond location 26, and the mechanical bonding has been configured to provide a first electrically conductive bond-path 30 between the first circuit-path and the second circuit-path through a thickness dimension 42 of at least the barrier layer 28 at the first bond location 26. Desirably, the mechanical bonding includes an ultrasonic bonding.

By incorporating its various aspects and features, alone or in desired combinations, the method of the invention can provide a desired, electrically-conductive interconnecting pathway between electrically-conductive circuit-paths that are positioned on opposite sides of an electrically-insulating substrate. The method can efficiently and economically interconnect selected circuit-paths through the thickness dimension of an intervening barrier layer of electrically insulating material. The interconnecting conductive pathway can penetrate and extend through the thickness dimension of the substrate, and the formation of the interconnecting conductive pathway can be configured to operatively maintain desired properties of the substrate. For example, the formation of the interconnecting conductive pathway can be configured to operatively maintaining a desired liquid-impermeable, barrier property of the substrate. As a result, the interconnecting conductive pathway can be positioned at a greater range of locations and can help provide greater versatility. For example, when the conductive pathway interconnects a circuit-path that is positioned on one side of the insulating substrate to a cooperating sensor or other external electrical monitoring device that is positioned on an opposite side of the substrate, the conductive pathway can have a location that allows a convenient cooperative positioning of the monitoring device at a location that provides improved comfort to the wearer.

In an additional aspect, the formation of the interconnecting conductive pathway can be configured to provide a desired level of mechanical bonding strength between selected components. As a result, the formation of the interconnecting conductive pathway can be configured to provide improved reliability. Where the first electrically-conductive circuit-path has been applied to a first substrate, and the second electrically-conductive circuit-path has been applied to a second substrate, the distribution and arrangement of the mechanical bonding can be configured to supplement the mechanical strength of the interconnecting pathway and increase the durability of the conductive bond-path. For example, a portion of the first substrate (e.g. a portion which is located adjacent the first circuit-path) can be bonded to a portion of the second substrate (e.g. a portion which is located adjacent the second circuit-path) to supplement the mechanical strength of the corresponding, local bond-path, and thereby increase the total mechanical strength of the bonded, interconnecting, conductive pathway. The higher mechanical strengths can help reduce electrical failures of the conductive pathway through mechanical fatigue of the interconnecting conductive pathway. The fatigue may, for example, arise from stresses and strains generated by the movements of a user. Additionally, more complex arrays of circuit-paths can be produced with fewer layers of substrate material. The reduced layers of substrate material can help reduce the thickness of the overall end-product, and can help increase the flexibility of the desired end-product.

The first electrically-conductive circuit-path 22 can include a first electrically-conductive material, and the second electrically-conductive circuit-path 24 can include a second electrically-conductive material. The first electrically-conductive material and the second electrically-conductive material can be different or substantially the same, as desired. Similarly, any additional, electrically-conductive circuit-paths can include a corresponding electrically conductive material, and each electrically-conductive material can be different or substantially the same as any other employed, electrically-conductive material. In the various arrangements of the method, an individual circuit-path can include any operative conductive material. Suitable conductive materials can, for example, include gold, silver, copper, aluminum, nickel, cobalt, carbon-doped materials, conductive polymers or the like, as well as combinations thereof. The conductive materials may have the form of conductive foils, conductive laminates, conductive traces, conductive inks or the like, as well as combinations thereof.

It should be appreciated that an individual circuit-path may include additional components, which may be electronic or non-electronic. The electronic components may include passive components, such as resistors, capacitors, inductors or the like, as well as combinations thereof. The active components may include transistors, diodes, operational amplifiers, integrated-circuit components, microprocessor components or the like, as well as combinations thereof.

The first, electrically-insulating barrier layer 28, as well as any other employed electrically-insulating layer, can be provided by employing any operative technique. For example, the selected barrier layer can be integrally formed with a corresponding conductive material employed in a corresponding circuit-path. Alternatively, the selected barrier layer can be a separately provided layer of barrier material that is subsequently assembled to a corresponding or associated circuit-path material. The barrier layer may be substantially monolithic or may include subcomponents, sub-layers, lamina, strata or the like, as desired.

In the various arrangements of the method, an individual, electrically-insulating barrier layer can include any operative, electrically-insulating material. Suitable electrically-insulating materials can, for example, include glass, glass fibers, cellulose, cellulose fibers, rubber, natural or synthetic elastomers, elastomeric fibers, plastics, polymer films or the like, as well as combinations thereof.

With reference to FIGS. 1 and 1A, the first electrically-conductive circuit-path 22 can be applied to a first substrate which is substantially nonconductive to electrical currents; and the first substrate can be configured to provide the first, electrically-insulating barrier layer 28. In a particular configuration, the first electrically conductive circuit-path 22 can be applied to a first major, facing-surface 32 of the first substrate; and the second electrically-conductive circuit-path 24 can be applied to an opposite, second major facing-surface 34 of the first substrate.

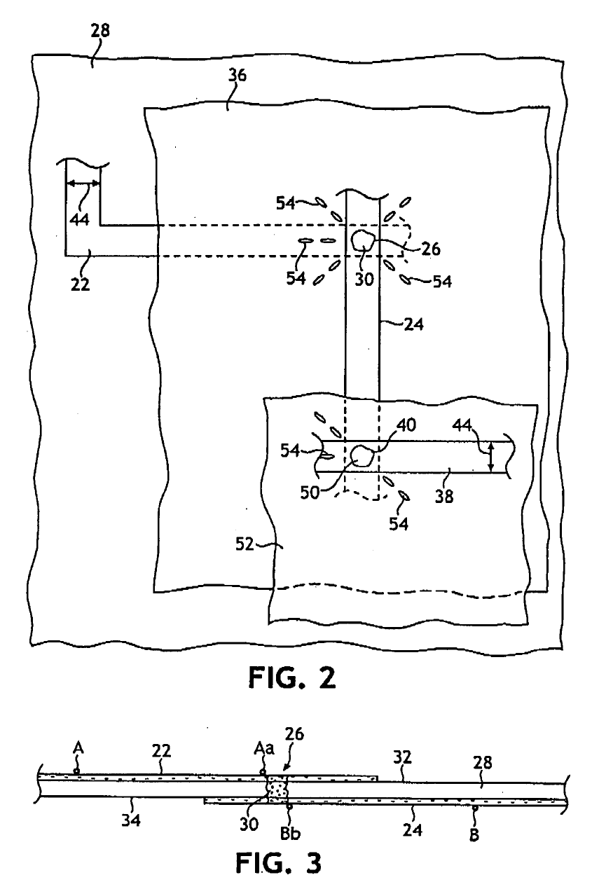

With reference to FIG. 2, an alternative arrangement can have the first, electrically-conductive circuit-path 22 applied to a first major, facing-surface 32 of the first substrate; and can have the second, separately provided electrically-conductive circuit-path 24 applied to a second substrate. In a desired feature, an individual substrate may be configured to be substantially nonconductive to electrical currents. Accordingly, the first substrate can be configured to provide a first, electrically-insulating barrier layer 28, and the second substrate can be configured to provide a second, electrically-insulating barrier layer 36.

In a particular arrangement, the mechanical bonding employed to form the conductive pathway (e.g. electrically-conductive bond-path 30) can be configured to provide increased reliability by supplementing the mechanical strength of the interconnecting pathway. For example, at least a selected portion of the first substrate (e.g. a portion of the barrier layer 28 that is adjacent the bond-path 30) can be bonded to at least a selected portion of the second substrate (e.g. a portion of the barrier layer 36 that is adjacent the bond-path 30) to provide a one or more supplemental bond 54 that can help increase the mechanical strength of the corresponding local bond-path and increase a total mechanical attachment strength of the adjacently bonded, interconnecting, conductive pathway. The higher, mechanical attachment strengths can help reduce electrical failures of the conductive pathway caused by a mechanical fatigue of the interconnecting conductive pathway. Such fatigue may arise from stresses and strains generated by ordinary movements of a user.

Additionally, the presented method may include providing a third, electrically-conductive circuit-path 38, and positioning a portion of the second circuit-path 24 proximally adjacent a portion of the third circuit-path 38 at a second predetermined bond location 40. The second electrically-insulating barrier layer 36 can be interposed between the second circuit-path 24 and the third circuit-path 38 at the second bond location 40, and the second circuit-path 24 can be mechanically bonded to the third circuit-path 38 at the second bond location, with the mechanical bonding configured to operatively provide a second electrically conductive bond-path 50 between the second circuit-path 24 and the third circuit-path 38 through the thickness dimension 42 of the second barrier layer 36 at the position of the second bond location 40.

With reference to FIG. 2, for example, a representative configuration can have the first circuit-path 22 located on and operatively attached to a first substrate (e.g. barrier layer 28); a second circuit-path 24 located on and operatively attached to a second substrate (e.g. barrier layer 36); and a third circuit-path 38 located on and operatively attached to a third substrate (e.g. barrier layer 52). In particular aspects, the first circuit-path 22 can be operatively connected to the second circuit-path 24 along a first electrically-conductive bond-path 30 which extends through the thickness of the second substrate. Additionally, the second circuit-path 24 can be operatively connected to the third circuit-path 38 along another separately provided, electrically-conductive bond-path 50 which extends through the thickness of the third substrate. As a result, more complex arrays of circuit-paths can be more efficiently produced with fewer layers of substrate material. The reduced layers of substrate material can help reduce the thickness of the overall end-product, and can help increase the flexibility of the desired end-product.

In a similar manner, additional electrically-conductive circuit-paths and additional electrically-insulating barrier layers may be stacked in alternating fashion to interpose the electrically-insulating barrier layers between corresponding circuit-paths at corresponding, predetermined bond locations, to provide further combinations and more complex configurations of the method. Portions of corresponding circuit-paths can be operatively positioned proximally adjacent each other at corresponding, predetermined corresponding bond locations, and mechanical bonding can be employed to provide electrically conductive bond-paths between the circuit-paths on opposite sides of a corresponding barrier layer at the corresponding bond locations.

An individual substrate layer or electrically-insulating barrier layer can be provided by any suitable material. For example, the substrate or barrier material can include a polymer film, a woven fabric, a nonwoven fabric, a spunbond fabric, a meltblown fabric, a coform fabric material, an elastomeric film, an elastomeric composite material, a non-conductive coating, a non-conductive laminate or the like, as well as combinations thereof.

An individual substrate layer or barrier layer can include natural and/or synthetic materials. In desired arrangements, an individual substrate layer or barrier layer can include a synthetic polymer material. Such polymer materials can, for example, include polyethylene, polypropylene, polyester, melt-extrudable polymer fabrics or the like, as well as combinations thereof.

An individual substrate layer or electrically-insulating barrier layer can be provided by a material having a selected softening point. For the purposes of the present disclosure, the softening point is the temperature at which the material can plastically flow in an operative manner. The plastic flow of the material may be initiated by any of the bonding methods or techniques described herein. In a particular aspect, the softening point temperature of the individual substrate or barrier material can be at least a minimum of about 38° C. The softening point can alternatively be at least about 50° C., and can optionally be at least about 60° C. to provide desired benefits. In other aspects, the softening point of the individual substrate or barrier material can be up to a maximum of about 150° C., or more, to provide desired effectiveness.

If the softening point temperature is too low, excessive deformation problems may occur at the bond locations, and the electrical conductivity at the bond location may be excessively low. If the softening point temperature is too high, the desired mechanical bond may not be achieved, and the electrical conductivity at the bond location can be inadequate.

A suitable determination of the softening point temperature of a material is the Vicat softening temperature, which can be measured in accordance with ASTM D1525-06, Standard Test Method for Vicat Softening Temperature of Plastics. Generally stated, the Vicat softening temperature is the temperature at which a flat-ended needle penetrates the specimen to the depth of 1 mm under a specific load. The temperature reflects the point of softening to be expected when a material is used in an elevated temperature application. During the testing, a test specimen is placed in the testing apparatus so that the penetrating needle rests on its surface at least 1 mm from the edge. A load of 10N or 50N is applied to the specimen. The specimen is then lowered into an oil bath at 23 degrees C. The bath is raised at a rate of 50° C. per hour until the needle penetrates 1 mm. The test specimen is between 3 and 6.5 mm thick and at least 10 mm in width and length, and no more than three layers may be stacked to achieve a minimum thickness. The Vicat softening test determines the temperature at which the needle penetrates 1 mm. A suitable device for determining the softening point temperature can be an ATLAS HDV2 DTUL/Vicat tester, or an equivalent device.

Another feature of the presented method can include configuring the individual substrate layer or electrically-insulating barrier layer with a selected flexibility value. The flexibility pertains to the ability to be flexed or bowed repeatedly without rupturing, and to an ease of bending, which can range from pliable (high flexibility) to stiff (low flexibility). The flexibility and “hand” of a material can relate to the tactile qualities of a fabric or other material. Such tactile qualities can, for example, include parameters of softness, firmness, elasticity, fineness, resilience as well as other qualities that are perceived by touch. For example, see the Dictionary of Fiber & Textile Technology, published by Hoechst Celanese Corporation, North Carolina in 1990.

To measure a flexure rigidity (or stiffness) of a material and to obtain a corresponding flexibility value, the employed test usually is typically referred to as a flex or bending test. In general, the flexure rigidity is a resistance to bending, or more specifically, the bending couple at either end of a strip of unit width that is bent into a unit curvature in the absence of any tension (ASTM D1388).

To determine the flexibility value of a selected substrate, the test material is flexed by a four-point loading, bending test (ref: Handbook of Polymer Testing, Brown, R; Marcel Dekker, Inc, New York, Basel, 1999). A suitable four-point loading, bending test is the KES Pure Bend test. This test can be conducted with a KAWABATA, model KES-FB-2 Bending Tester, or a substantially equivalent device. The KAWABATA Bending Tester is available from KATO TECH CO., LTD., a business having offices located in Kyoto, Japan, and the KAWABATA device includes detailed instructions for conducting the KES Pure Bend test.

The KES Pure Bend test has a high sensitivity to measure flexible materials. Since the KES test is a pure bending test, there are only normal stresses with no shearing stresses. In the KES pure bend test, the bending rigidity values are obtained from the initial slopes of the bending curve which is bending between curvatures of −2.5 cm⁻¹ and 2.5 cm⁻¹, with a constant rate of curvature change at 0.5 cm⁻¹/sec.

The bending rigidity can be employed to provide flexibility values, where:
Bending Rigidity=averaged slope of the bending curve between curvatures of 0.5 cm⁻¹ and 1.5 cm⁻¹, and curvatures of −0.5 cm⁻¹ and −1.5 cm⁻¹.

In a particular aspect, the flexibility value (bending rigidity value) can be at least a minimum of about 0.0015 grams-force (gf)*cm²/cm. In other aspects, the flexibility value can be up to a maximum of about 0.03 gf*cm²/cm. The flexibility value can alternatively be up to about 0.028 gf*cm²/cm, and can optionally be up to about 0.025 gf*cm²/cm to provide desired effectiveness.

If the flexibility value is outside the desired values, the material may have an excessively harsh feel. Additionally, the material may allow excessive fatigue stresses and strains on associated circuit-paths, circuit components or circuit connections.

An individual, electrically-conductive circuit-path, such as the first circuit-path 22 and/or the second circuit-path 24, can be applied by printing a corresponding electrically-conductive material from a liquid-state of the associated electrically-conductive material. For example, the first electrically-conductive circuit-path can be applied by printing a first electrically-conductive material from a liquid-state of the first electrically-conductive material; and the second electrically-conductive circuit-path can be applied by printing a second electrically-conductive material from a liquid-state of the second electrically-conductive material.

An individual, electrically-conductive material may include an electrically-conductive ink. The conductive ink includes electrically-conductive materials, and can be formulated for printing onto the selected substrate using various printing processes. The conductive ink typically includes a vehicle including one or more resins and/or solvents. Various other ink additives known in the art, e.g., antioxidants, leveling agents, flow agents and drying agents, may be included in the conductive ink. The conductive ink can be in the form of a paste, slurry or dispersion. The ink generally also includes one or more solvents that readily can be adjusted by the skilled practitioner for a desired rheology. The ink formulation is desirably mixed in a grinding mill to sufficiently wet the conductive particles with the vehicle, e.g., solvent and resin.

The conductive material can include silver, copper, gold, palladium, platinum, carbon, or combinations of these particles. The average particle size of the conductive material can be within the range of between about 0.5 μm and about 20 μm. Desirably, the average particle size can be between about 2 μm and about 5 μm. Alternatively, the average particle size can be about 3 μm. The amount of conductive material in the conductive trace or circuit-path can be between about 60% and about 90%, on a dry weight basis. Desirably, the amount of conductive material in the conductive trace can be between about 75% and about 85%, on a dry weight basis.

The electrically-conductive particles can be flakes and/or powders. In particular arrangements, the conductive flakes have a mean aspect ratio of between about 2 and about 50, and desirably between about 5 and about 15. The aspect ratio is a ratio of the largest linear dimension of a particle to the smallest linear dimension of the particle. For example, the aspect ratio of an ellipsoidal particle is the diameter along its major axis divided by the diameter along its minor axis. For a flake, the aspect ratio is the longest dimension across the length of the flake divided by its thickness.

Suitable conductive flakes may include those sold by METALOR (a business having offices located in Attleboro, Mass., U.S.A.) under the following trade designations: P185-2 flakes having a particle size distribution substantially between about 2 μm and about 18 μm; P264-1 and P264-2 flakes having particle size distributions substantially between about 0.5 μm and about 5 μm; P204-2 flakes having a particle size distribution substantially between about 1 μm and about 10 μm; P204-3 flakes having a particle size distribution substantially between about 1 μm and about 8 μm; P204-4 flakes having a particle size distribution substantially between about 2 μm and about 9 μm; EA-2388 flakes having a particle size distribution substantially between about 1 μm and about 9 μm; SA-0201 flakes having a particle size distribution substantially between about 0.5 μm and about 22 μm and having a mean value of about 2.8 μm; RA-0001 flakes having a particle size distribution substantially between about 1 μm and about 6 μm; RA-0015 flakes having a particle size distribution substantially between about 2 μm and about 17 μm; and RA-0076 flakes having a particle size distribution substantially between about 2 μm and about 62 μm, and having a mean value of about 12 μm.

Suitable silver powders may include those sold by METALOR under the following trade designations: C-0083P powder having a particle size distribution substantially between about 0.4 μm and about 4 μm, and having a mean value of about 1.2 μm; K-0082P powder having a particle size distribution substantially between about 0.4 μm and about 6.5 μm, and having a mean value of about 1.7 μm; and K-1321P powder having a particle size distribution substantially between about 1 μm and about 4 μm.

The conductive ink may include a resin. Suitable resins can, for example, include polymers, polymer blends, fatty acids or the like, as well as combinations thereof. In particular arrangements, alkyd resins may be employed. Examples of such resins include LV-2190, LV-2183 and XV-1578 alkyd resins from Lawter International (a business having offices located in Kenosha, Wis., U.S.A.). Also suitable are Crystal Gloss Metallic Amber resin, Z-kyd resin, and alkali refined linseed oil resin available from Kerley Ink (a business having offices located in Broadview, Ill., U.S.A.). Soy resins, such as those available from Ron Ink Company (a business having offices located in Rochester, N.Y., U.S.A.) are also suitable.

Solvents for use in the conductive ink formulation are well known in the art, and a person can readily identify a number of suitable solvents for use in a particular printing application. Solvents can generally comprise between about 3% and about 40% of the ink by weight on a wet basis. The amount may vary depending on various factors including the viscosity of the resin, the solvation characteristics of the solvent, and the conductive particle size, distribution and surface morphology for any given printing method. Generally, the solvent can be added to the ink mixture until a desired ink rheology is achieved. The desired rheologies can depend on the printing method used, and are well known by skilled printers and ink manufacturers.

The solvent in the conductive ink can include non-polar solvents such as a hydrocarbon solvent, water, an alcohol such as isopropyl alcohol, and combinations thereof. Particular arrangements may employ an aliphatic hydrocarbon solvent. Examples of suitable solvents include ISOPAR H aliphatic hydrocarbon solvent from Exxon Corporation (a business having offices located in Houston, Tex., U.S.A.); EXX-PRINT M71a and EXX-PRINT 274a aliphatic and aromatic hydrocarbon solvent from Exxon Corporation; and MCGEE SOL 52, MCGEE SOL 47 and MCGEE SOL 470 aliphatic and aromatic hydrocarbon solvent from Lawter International (Kenosha, Wis., U.S.A.).

Various printing techniques can be employed to produce an individual, electrically-conductive circuit-path or trace. The printing techniques are conventional and commercially available. For example, the electrically-conductive ink can be applied to the selected substrate using printing techniques known in the art for printing inks on paper and other substrates, including, but not limited to, offset-lithographic (wet, waterless and dry), flexographic, rotogravure (direct or offset), intaglio, ink jet, electrophotographic (e.g. laser jet and photocopy), and letterpress printing. These printing methods are desirable because conventional methods for forming traces on circuit boards include multiple steps (e.g., photoresist, cure and etching) are time intensive, environmentally unfriendly, and relatively expensive. Commercial printing presses preferably are used for printing on the substrates of the present invention. Commercial printing presses may require additional drying capability to dry the ink after printing or require modifications to handle polymer films (e.g., to handle electrostatic charge). These types of modifications are known in the art and typically can be ordered when purchasing a commercial printing press. Depending on the printing technology, printing speed in the range of from about 150 feet per minute to about 300 feet per minute readily can be achieved. It is envisioned that even greater printing speeds can be achieved, e.g., about 1000 feet per minute or more.

The electrically-conductive ink can desirably be deposited in a quantity such that the dried conductive trace or circuit-path has a thickness dimension which is within the range of about 1 μm to about 8 μm, depending on the printing process used. For example, a single printing operation which provides an ink film thickness of about 2 μm to about 3 μm is typically sufficient to achieve sufficient conductivity. The conductive ink optionally can be printed on the selected substrate two or more times to deliver more conductive ink to the selected substrate. In particular arrangements, the conductive ink is printed only once to avoid the registration problems that may arise when printing multiple times.

Optionally, the conductive ink may be dried at a selected drying temperature to help form the desired conductive trace or circuit-path. In a particular aspect, the drying can be conducted prior to a step of embedding the trace into its associated, cooperating substrate. The drying temperature is desirably selected to avoid excessive damage to the substrate or barrier layer material.

The conductive ink may be dried at the selected drying temperature to drive off some or all of the solvent or carrier to minimize any bubbles containing trapped solvent, and/or to minimize pin holes or craters from rapid solvent evaporation. The conductive ink can be dried using an oven, such as a convection oven, or using infrared, and radio frequency drying, or ultraviolet (UV) radiation. In a particular arrangement, the heating device may be designed to allow the printed substrate to pass therethrough so that the conductive ink can be dried in a continuous manner to facilitate large-scale production. The drying temperature employed depends on the ink used, the softening temperature of the selected substrate, and the drying time or belt speed. Typical drying temperatures can be within the range of about 125° F. to about 150° F. (about 52° C.-66° C.). When UV is employed, the drying temperature may be at room temperature. After the drying step, the circuit element can be allowed to cool prior to the optional embedding step. Alternatively, the drying step can be achieved continuously with the embedding step as the trace is heated to the drying temperature.

In the various configurations of the method, the mechanical bonding can be provided by a bonding wherein at least about 80% of an applied bonding energy has been provided by mechanical (e.g. vibrational) or electromagnetic, energy-bearing frequencies that are below the frequency of infrared radiation. Desirably, at least about 90%, and more desirably, up to about 100%, of the applied bonding energy has been provided by energy-bearing frequencies that are below the frequency of infrared radiation. More particularly, the mechanical bonding can be induced by applied mechanical or electromagnetic energy-frequencies that are below 300 GHz (Giga-Hertz). Accordingly, the mechanical bonding that has been induced by energy-frequencies which substantially exclude the frequencies of infrared radiation, and substantially exclude frequencies that are higher than those of infrared radiation. The mechanical bonding may, for example, include ultrasonic bonding, pressure bonding, radio-frequency welding, microwave welding or the like, as well as combinations thereof. In desired arrangements, the presented method can incorporate ultrasonic bonding, or a combination of ultrasonic bonding and pressure bonding.

The employed mechanical bonding forms a mechanical bond which can provide an operatively continuous, electrical connection. In a desired feature, the mechanical bonding can form an operative, electrically-conductive interconnection along the bond-path (e.g. bond-path 30) through the thickness of the barrier layer material (e.g. barrier layer 28) that is interposed between cooperating circuit-paths (e.g. between the first circuit-path and its cooperating second circuit-path). The electrical-conductivity through the mechanical bond can be a function of the electrical-conductivity of the component materials employed to form the individual circuit-paths that are interconnected by the bond-path. In a particular aspect, the conductivity through the bond-path can be at least about 80 percent of the conductivity of the circuit-path having the relatively lower conductivity. Desirably, the conductivity through the bond-path can be at least 90% of the conductivity of the circuit-path having the relatively lower conductivity. More desirably, the conductivity through the mechanical bond can be at least 95% of the conductivity of the circuit-path having the relatively lower conductivity.

Ultrasonic bonding is a conventional method of operatively bonding solid materials by applying a moderate clamping pressure to a selected bond region and subjecting the selected bond region to vibratory shearing action at ultrasonic frequencies until a desired bond is achieved. Detailed descriptions of ultrasonic bonding systems are described in various publications. For example, see U.S. Pat. No. 5,591,298 entitled MACHINE FOR ULTRASONIC BONDING, which was issued Jan. 7, 1997; and U.S. Pat. No. 6,517,671 entitled RAMPED ULTRASONIC BONDING ANVIL AND METHOD FOR INTERMITTENT BONDING by Jack Lee Couillard et al., which was issued Feb. 11, 2003.

In desired configurations of the method, the individual conductive materials in at least the portions of the circuit-paths located at an individual, bond location (26, 40), can have a selected thickness dimension. As representatively shown, for example, the conductive material of the first circuit-path 22 can have a thickness 23, and the conductive material of the second circuit-path 24 can have a thickness 25. A particular feature can configure at least the portions of the conductive materials at an individual, bond location with a selected, combined thickness, as determined prior to the subsequent bonding operation. In a particular aspect, the combined thickness of the conductive materials in the circuit-paths appointed for bonding can be of at least a minimum of about 9 μm. The combined thickness of the conductive materials at the individual bond location can alternatively be at least about 10 μm, and can optionally be at least about 12 μm to provide improved performance. In other aspects, the combined thickness of the conductive materials at the individual bond location (as determined prior to bonding) can be up to about 50 μm, or more, to provide desired benefits.

In a further feature, the conductive materials in at least the portions of the circuit-paths located at an individual, bond location (26, 40) can have a selected, combined thickness (prior to bonding) which is a selected percentage of the thickness of the substrate or barrier layer that is interposed between the circuit-paths appointed for bonding. In a particular aspect, the combined thickness (prior to bonding) can be at least a minimum of about 5% of the thickness of the interposed substrate or barrier layer. The combined thickness can alternatively be at least about 25% of the thickness of the interposed substrate or barrier layer, and can optionally be at least about 50% of the thickness of the interposed substrate or barrier layer to provide improved performance. In other aspects, the combined thickness of the conductive materials at the individual bond location can be up to about 60%, or more, of the thickness of the interposed substrate or barrier layer to provide desired benefits.

The bonding operation can include an operative bonding with a selected bond pattern, and the bonding pattern can be configured to substantially avoid breaking or otherwise excessively disrupting the desired electrically-conductive pathway which extends from the first circuit-path to the second circuit-path through their corresponding, interconnecting bond-path. The bond pattern can be significantly discontinuous, and in desired configurations, the bond pattern can be provided by a bonding mechanism having a plurality of bonding members (e.g. bonding pins) distributed in an intermittent, distributed array over the appointed bonding location, where the individual bonding members are spaced apart and operatively configured to provide a selected percentage of closed, bonding area. In a particular aspect, the percent bonded area can be at least a minimum of about 5%. The percent bonded area can alternatively be at least about 7%, and can optionally be at least about 10% to provide desired benefits. In another aspect, the percent bonded area can be up to a maximum of about 50% or 60%. The percent bonded area can alternatively be up to about 30% or 40%, and can optionally be up to about 20% to provide desired performance. In a particular arrangement, the percent bonded area can be about 13%.

An individual, electrically-conductive circuit-path (e.g. circuit-path 22 and/or circuit-path 24) can have a selected electrical resistivity value, particularly in a generally proximal vicinity of its corresponding bond location. In a desired aspect, the resistivity value can be substantially zero Q/m (ohms/meter). In other aspects, the electrical resistivity value can be not more than a maximum of about 1 MΩ/m (mega-ohms/meter). The resistivity value can alternatively be not more than about 1 KΩ/m (kilo-ohms/meter), and can optionally be not more than about 100 Ω/m to provide improved effectiveness.

In another aspect, the resistivity value of an individual, electrically-conductive circuit-path can be substantially zero ohms per square per mil of the electrically-conductive material (Ω/square per mil), where: 1 mil=0.001 inch. The resistivity value can alternatively be as low as 0.1 Ω/square per mil, and can optionally be as low as 1 Ω/square per mil. In still other aspects, the resistivity value can be not more than a maximum of about 33 KΩ/square per mil. The resistivity value can alternatively be not more than about 16 KΩ/square per mil, and can optionally be not more than about 8 KΩ/square per mil to provide improved effectiveness.

A suitable procedure for determining the resistivity values in terms of “ohms per square per mil” is ASTM F 1896-98 (Reapproved 2004), Test Method for Determining the Electrical Resistivity of a Printed Conductive Material.

A further aspect of the presented method can have a configuration in which an individual, electrically-conductive bond-path (e.g. electrical bond-path 30 and/or 50) has been configured to provide a selected, electrical resistance value. In particular aspects, the resistance value can be as low as zero ohms. The resistance value can alternatively be as low as 0.1Ω, and can optionally be as low as 0.5Ω to provide desired performance. In other aspects, the electrical resistance value can be not more than a maximum of about 1 KΩ. The resistance value can alternatively be not more than about 100Ω, and can optionally be not more than about 10Ω to provide improved performance.

If the resistance value is too large, or is otherwise outside the desired values, excessive power consumption and excessive design complexity can arise. Additionally, the measurement sensitivity and measurement accuracy in associated circuits may be degraded.

With reference to FIG. 3, the resistance of an individual bond-path can be determined by employing the following procedure: (a) Measure the resistance of the first circuit-path from an operative point A, to a point Aa that is immediately adjacent the bond-path and is relatively closest to point A, to determine a first, resistance value R1. (b) Measure the resistance of the second circuit-path from an operative point B, to a point Bb that is immediately adjacent the bond-path and is relatively closest to point B, to determine a second, resistance value R2. (c) Measure the overall resistance along a path that runs directly from point A to Aa, directly through the bond-path, and directly from point Bb to point B, to determine a total resistance value R_{T}.

Then: R_{B}=R_{T}−R1−R2; where R_{B}=resistance of the individual bond-path that is interposed between point A and point B.

An individual, electrical bond location can also be configured to provide a selected bond-strength. In a particular aspect, the bond-strength can be increased when the first, electrically conductive circuit-path 22 has been applied to a first major, facing-surface 32 of a first substrate (e.g. layer 28); and the second, separately provided electrically-conductive circuit-path 24 has been applied to a major facing-surface of a second substrate (e.g. layer 36).

The mechanical bond-strength at the bond location can be measured as a function of the component material strength, and in a particular aspect, can be at least 10 percent of the strength of the component material having the lowest component member strength. Desirably, the conductive mechanical bond strength can be at least 40 percent of the strength of the component material having the lowest component member strength. More desirably; the strength of the conductive mechanical bond can be at least 80 percent of the strength of the component material having the lowest component member strength.

In a particular feature, an individual bond location can have a selected bond strength, as measured in shear. The shear-strength of the bond at an individual bond location can be up to about 100%, or more, of the tensile strength of the weakest substrate or barrier material employed with the corresponding interconnected circuit-paths. The bond strength of the individual electrical bond location can alternatively be up to about 200%, or more, of the tensile strength of the weakest substrate or barrier material employed with the corresponding interconnected circuit-paths. The percent bond strength can optionally be up to about 300%, or more, of the tensile strength of the weakest substrate or barrier material employed with the corresponding interconnected circuit-paths to provide improved benefits. In another aspect, the shear-strength of a bond at an individual bond location can be at least about 10%, of the tensile strength of the weakest substrate or barrier layer material employed with the corresponding, interconnected circuit-paths. The percent bond, shear-strength of the individual electrical bond location can alternatively be at least about 40%, and can optionally be up to about 80% of the tensile strength of the weakest substrate or barrier material employed with the corresponding, interconnected circuit-paths to provide desired performance.

A suitable procedure for determining the tensile strength of a material is ASTM D3039/D3039M-00, Standard Test Method for Tensile Properties of Polymer Matrix Composite Materials. A suitable procedure for determining the shear-strength of a material is ASTM D3518/D3518M-94, Standard Test Method for In-Plane Shear Response of Polymer Matrix Composite Materials by Tensile Test of a ±45° Laminate.

To determine the percent bond strength of an individual electrical bond location, the following calculation is employed:

% bond strength=100*(bond shear-strength)÷(substrate tensile-strength)

The bond location can have any operative configuration. For example, the bonding in the bond location can have any operative shape or distribution. The bonding shape may be irregular or substantially regular. The bonding distribution may be non-patterned or patterned, and a selected pattern may be regular or irregular, as desired. In a further feature, an individual electrical bond location can be configured to extend over a selected bond area. It should be recognized that the conductive, surface area of contact can significantly affect the resistivity value of the interconnecting bond-path. Desirably, the bonding is configured to produce a bonding area that provides for sufficient levels of strength and high conductivity.

In particular aspects, the bond area can be at least a minimum of about 3.5 mm². The bond area can alternatively be at least about 10 mm², and can optionally be at least about 25 mm² to provide desired benefits. In other aspects, the bond area can be up to a maximum of about 1000 mm², or more. The bond area can alternatively be up to about 100 mm², and can optionally be up to about 35 mm² to provide improved effectiveness.

If the bond area is outside the desired values, the strength and conductivity of the bond area and bond-path may be excessively low, or the bond area may excessively deplete the substrate area available for supporting the desired circuit-paths.

Another feature can have an individual bond location configured to be substantially liquid impermeable. More particularly, the bond location can be substantially liquid-impermeable in a region which extends over the bond area and past the perimeter of the bond area by a distance of about 1 mm. In the various configurations of the invention, the operatively liquid-impermeable material can have a construction which is capable of supporting a hydrohead of at least about 45 cm of water without allowing a significant level of leakage therethrough. A suitable technique for determining the resistance of a material to liquid penetration is Federal Test Method Standard FTMS 191 Method 5514, dated 31 Dec. 1968, or a substantially equivalent procedure.

In still another feature, an individual circuit-path (e.g. circuit-path 22, 24 and/or 38) can be provided with a selected cross-deckle width dimension 44 (e.g. FIGS. 1 and 2). In a particular aspect, the cross-deckle width can be at least a minimum of about 0.01 cm. The cross-deckle width can alternatively be at least about 0.02 cm, and can optionally be at least about 0.03 cm to provide [improved] desired benefits. In other aspects, the cross-deckle width can be up to a maximum of about 1 cm, or more. The cross-deckle width can alternatively be up to about 0.5 cm, and can optionally be up to about 0.1 cm to provide desired effectiveness.

If the cross-deckle width of an individual circuit-path is outside the desired values, the cost of the conductive material can be excessively high. As a result, the manufacturing costs of the end product can be outside the desired ranges.

It should be readily appreciated that the areas and width dimensions of an individual circuit-path, can be determined by employing standard microscopy techniques. Such techniques are conventional, and are well known in the art.

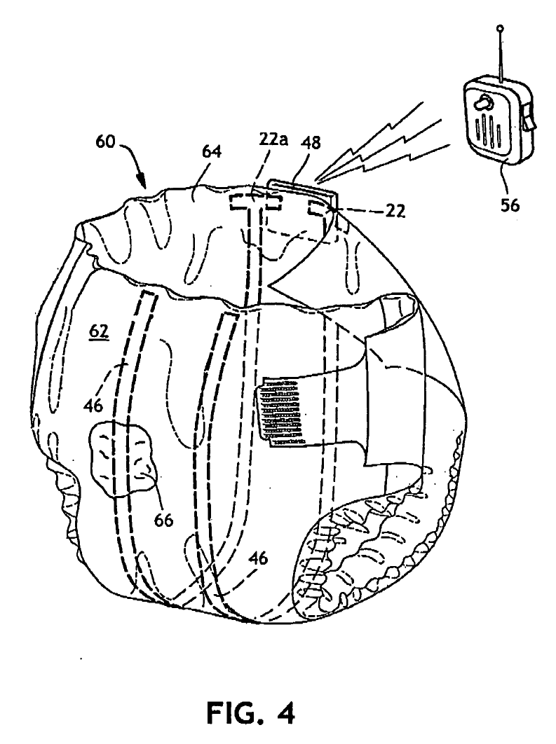

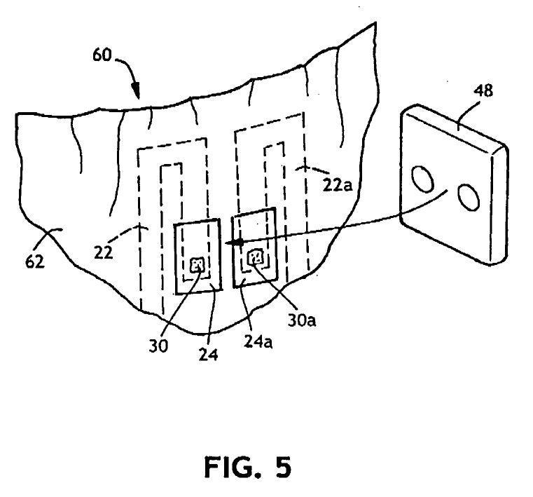

With reference to FIGS. 4 and 5, another aspect of the method can include at least one electrically conductive circuit-path (e.g. circuit-path 22) which has been operatively connected to a sensor mechanism 46 which can provide selected sensor data. In a further aspect, at least another electrically conductive circuit-path (e.g. circuit-path 24) can be operatively connected to an electronic processor mechanism 48 which can operatively receive the sensor data and provide selected signal data.

Any appropriate detecting, sensing or interrogating device or system may be operatively employed to provide the sensor mechanism 46 that is incorporated with the method. A suitable sensor mechanism may, for example, include a wetness sensor, a motion sensor, a temperature sensor, a humidity sensor, a pressure sensor, a position sensor, a proximity sensor, a light sensor, an odor sensor or the like, as well as combinations thereof.

It should be appreciated that any appropriate information or data may be operatively included in the sensor data that is generated with the method. Suitable sensor data can, for example, include data regarding resistance, voltage, capacitance, inductance, wetness, motion, temperature, humidity, pressure, position, proximity, light, odor or the like, as well as combinations thereof.

Any appropriate analyzing, computing or assessing device or system may be operatively included with the electronic processor mechanism 48. A suitable electronic processor mechanism can, for example, include a micro controller, a micro processor, an analog to digital converter, a FPGA (Field Programmable Gate Array), an EEPROM (Electrically Erasable Programmable Read-Only Memory), an electronic memory device or the like, as well as combinations thereof. The electronic processor can collect, process, store, analyze, convert digital or analog data, provide feedback or the like, as well as combinations thereof.

It should be appreciated that any appropriate information or data may be operatively included in the signal data that is generated with the method. Suitable signal data can, for example, include data pertaining to light, sound, tactile, odor, bio-electrical impulses, biometric data, motion, vibration, wireless communication or the like, as well as combinations thereof.

In desired arrangements, the electronic processor mechanism 48 may be configured to transfer the signal data to another, relatively remote location. As representatively shown, for example, the method of the invention may be configured to transmit signal data with a wireless communication link to a remote receiver device 56.

FIGS. 4 and 5 illustrate an example of a suitable article, such as the representatively shown personal care article, which can be configured to incorporate the present invention. As representatively shown, the article 60 can, for example, be configured to provide an infant diaper or a child-care training pant. The article can have an outercover layer 62, a first circuit-path disposed along a bodyside surface of the outercover, and at least a second circuit-path disposed along an outward, garment-side surface of the outercover. As representatively shown, a first supplemental circuit-path 22a can be disposed along the bodyside surface of the outercover; and a second supplemental circuit-path 24a can be disposed along the outward, garment-side surface of the outercover.

In a particular configuration, the first circuit-paths 22 and 22a can be operatively connected to a selected sensor mechanism. In the representatively shown arrangement, for example, the sensor mechanism can be a wetness sensor. The sensor mechanism can, for example, be configured to provide one or more of functions or operations pertaining to a wireless, audio, visual and/or tactile indication of a monitored event. Additionally, the sensor mechanism can, for example, be configured to provide one or more of functions or operations pertaining to a number of events, lengths of time between events, as well as any other statistics pertaining to a selected event, as desired by a user. As representatively shown, the sensor mechanism can be an internal sensor that is configured to detect a presence of aqueous liquid, which is within the article 60 and is present above a selected threshold level.

Additionally, the second circuit-paths 24 and 24a can be operatively connected to a selected electronic processor mechanism. In the representatively shown arrangement, for example, the electronic processor mechanism can be a microcontroller. The electronic processor mechanism can, for example be configured to convert data (Analog to Digital, or Digital to Analog), store data, trigger a predetermined response, allow for user interrupt, provide signal conditioning, compute and process algorithms or the like, as well as combinations thereof.

As representatively shown, at least a selection portion of the first circuit-path (22 and/or 22a) is positioned proximally adjacent at least an operative portion of the second circuit-path (24 and/or 24a) at a first predetermined electrical bond location 26. The outercover 62 has a position that is interposed between the first and second circuit-paths, and is composed of a material that provides an electrically-insulating barrier layer which is interposed between the first circuit-path and second circuit-path at the first bond location. The first circuit-paths 22 and/or 22a are configured to operatively connect to the second circuit-paths 24 and/or 24a through the thickness dimension of the outercover 62 with a mechanical bond positioned at the first bond location. Desirably, the mechanical bond includes an ultrasonic bond. The mechanical bonding is configured to provide an electrically conductive bond-path 30 between the appointed first circuit-path and the appointed second circuit-path at the first bond location. As representatively shown, a separately provided, external, electronic processor mechanism 48 can be operatively connected to the second circuit-paths 24 and/or 24a. In desired arrangements, the electronic processor mechanism 48 can be removably attached or otherwise removably connected to the second circuit-paths 24 and/or 24a on the outside surface of the outercover 62. Accordingly, the electrically conductive bond-path can be employed to operatively connect the internally positioned sensor mechanism to the separately provided, external, electronic processor mechanism with an operative, electrically-conductive connection.

The article 60 can also include a topsheet or bodyside liner layer 64, and an absorbent structure 66 positioned between the outercover layer 62 and topsheet layer 64. Additionally, the article 60 can include other components, such as fasteners, elastic members, transfer layers, distribution layers or the like, as desired, in conventional arrangement that are well known in the art.

The outercover layer 62 may be constructed of any operative material, and may or may not be configured to be operatively liquid-permeable. In a particular configuration, the outercover layer 62 may be configured to provide an operatively liquid-impermeable layer. The outercover layer may, for example, include a polymeric film, a woven fabric, a nonwoven fabric or the like, as well as combinations or composites thereof. For example, the outercover layer 62 may include a polymer film laminated to a woven or nonwoven fabric. In a particular feature, the polymer film can be composed of polyethylene, polypropylene, polyester or the like, as well as combinations thereof. Additionally, the polymer film may be micro-embossed. Desirably, the outercover layer 62 can operatively permit a sufficient passage of air and moisture vapor out of the article, particularly out of an absorbent (e.g. storage or absorbent structure 66) while blocking the passage of bodily liquids.

The topsheet layer 64 may be constructed of any operative material, and may be a composite material. For example, the topsheet layer can include a woven fabric, a nonwoven fabric, a polymer film, or the like, as well as combinations thereof. Examples of a nonwoven fabric include, spunbond fabric, meltblown fabric, coform fabric, a carded web, a bonded-carded-web, or the like as well as combinations thereof. For example, the topsheet layer can include a woven fabric, a nonwoven fabric, a polymeric film that has been configured to be operatively liquid-permeable, or the like, as well as combinations thereof. Other examples of suitable materials for constructing the topsheet layer can include rayon, bonded-carded webs of polyester, polypropylene, polyethylene, nylon, or other heat-bondable fibers, polyolefins, such as copolymers of polypropylene and polyethylene, linear low-density polyethylene, aliphatic esters such as polylactic acid, finely perforated film webs, net materials, and the like, as well as combinations thereof.

The topsheet layer 64 can also have at least a portion of its bodyside surface treated with a surfactant to render the topsheet more hydrophilic. The surfactant can permit arriving bodily liquids to more readily penetrate the topsheet layer. The surfactant may also diminish the likelihood that the arriving bodily fluids, such as menstrual fluid, will flow off the topsheet layer rather than penetrate through the topsheet layer into other components of the article (e.g. into the absorbent body structure 66). In a particular configuration, the surfactant can be substantially evenly distributed across at least a portion of the upper, bodyside surface of the topsheet layer 64 that overlays the upper, bodyside surface of the absorbent.

The topsheet layer 64 typically extends over the upper, bodyside surface of the absorbent structure, but can alternatively further extend around the article to partially or entirely, surround or enclose the absorbent structure. Alternatively, the topsheet layer 64 and the outercover layer 62 can have peripheral margins which extend outwardly beyond the terminal, peripheral edges of the absorbent structure 66, and the extending margins can be joined together to partially or entirely, surround or enclose the absorbent structure.

The structure of the absorbent body 66 can include a matrix of absorbent fibers and/or absorbent particulate material. The absorbent fiber can include natural or synthetic fiber. The absorbent structure 66 may also include superabsorbent material, and the superabsorbent material may be in the form of particles having selected sizes and shapes. Superabsorbent materials suitable for use in the present invention are known to those skilled in the art. As a general rule, the water-swellable, generally water-insoluble, hydrogel-forming polymeric absorbent material (superabsorbent) is capable of absorbing at least about 10, desirably about 20, and possibly about 100 times or more its weight in water.

Additionally, the absorbent body structure 66 can comprise a composite. The absorbent composite can, for example, include an intake layer, a distribution layer and/or a storage/retention layer, as desired.

An example of a personal care article that includes a sensor system is described in U.S. patent application Ser. No. 11/303,283 entitled GARMENTS WITH EASY-TO-USE SIGNALING DEVICE by Andrew Long, et al. (attorney docket number 22,139), which was filed Dec. 15, 2005. The entire disclosure of this document is incorporated herein by reference in a manner that is consistent herewith.

The technique of the invention can, for example, be configured to provide a wetness indicator for a product with a placement of a semi-durable alarm component anywhere on the product outer surface of the outercover without compromising the liquid-impermeable barrier properties of the outercover. In other configurations, the technique of the invention may be employed to produce an EKG jacket, which has an internal wiring harness incorporated into the disposable material used to construct the jacket. The jacket can also have a conductive pathway through the thickness of the jacket material which operatively interconnects the wiring harness to an electrical interface located on an outside surface of the jacket. The interface can, in turn, operatively connect to an EKG monitoring device or system. In still other configurations, the technique of the invention may be employed to produce electrical connections to sensors embedded in sterile wraps or bandages without compromising a desired, liquid-impermeable barrier property of the wrap or bandage.

The following Examples describe particular configurations of the invention, and are presented to provide a more detailed understanding of the invention. The Examples are not intended to limit the scope of the present invention in any way. From a complete consideration of the entire disclosure, other arrangements within the scope of the claims will be readily apparent to one skilled in the art.

### EXAMPLES 1-3

A first material was a composite film composed of 12 μm thick polyester substrate layer and a first circuit-path provided by a 12 μm thick aluminum foil. It is believed that the 12 μm thick aluminum circuit-path could be readily provided by printing a conductive aluminum ink onto the polyester substrate. A second material was composed of 0.75 mil (0.00075 inch) thick poly film with a second, 100 nm thick copper circuit-path printed on one side of the film.

Prior to bonding, the materials were arranged such that the copper circuit-path was on one side of the 0.75 mil poly film, and the aluminum circuit-path was against an opposite side of the 0.75 mil poly film. The aluminum circuit-path was operatively aligned with the copper circuit-path, and the aluminum foil material was bonded to the printed-copper circuit-path through the thickness of the 0.75 mil poly film. A BRANSON ultrasonic bonder Model 931 was used to bond the samples. The 20 kHz bonder was set at a 50 PSI bonding pressure and was set in an energy mode which limited the energy to 670 Joules. Bonding time was allowed to be variable. The ultrasonic horn of the bonder was a 6 inch by ⅜ inch, 3 gain horn, and was positioned against the printed copper circuit-path selected for bonding. The anvil of the bonder was positioned against the polyester substrate that carried the aluminum foil circuit-path, and was operatively aligned with the aluminum circuit-path. The anvil was configured to provide a discontinuous bonding pattern provided by a plurality of circular, frusta-conical bonding pins with the bonding pins having a 40 degree cone angle, a top diameter of about 0.965 mm and a height of about 0.889 mm. The bonding pins were distributed in a generally staggered array over the bonding location. Additionally, the bonding pins were configured to provide a percentage of closed, bonding area of about 13.3%. Three bonded samples were produced, and the results of the bonding operations are summarized in the following Table 1.

TABLE 1

| | Energy | Time | Resistance | |
|---|---|---|---|---|
| Sample | (Joules) | (ms) | (Ohms) | Comments |
| 1 | 67 | 198 | 4.5 | |
| 2 | 67 | 93 | 4.3 | |
| 3 | 70 | 101 | 7.6 | The conductive materials were |
| | | | | poorly aligned with this sample |

### COMPARATIVE EXAMPLE 4

A first material was composed of a first 0.75 mil poly film with a first, copper circuit-path conductively printed on one surface of the film at a thickness of approximately 100 nm. A second material was composed of a second 0.75 mil thick poly film with a second, 100 nm thick copper circuit-path printed on one side of the second film.

Prior to bonding, the materials were arranged such that the first copper circuit-path was on one side of the first, 0.75 mil poly film, and the second, copper circuit-path was placed against an opposite side of the first, 0.75 mil poly film. The second, copper circuit-path was operatively aligned with the first, copper circuit-path, and the first, copper circuit-path was bonded to the second, copper circuit-path through the thickness of the first 0.75 mil poly film. The BRANSON ultrasonic bonder Model 931 was used to bond the samples.

Bond pressure, energy, time and anvil surfaces were changed in attempts to form a conductive bond-path between the first and second copper circuit-paths through the thickness of the film material, but the generated bond-paths had excessively high resistances of greater than 1 M-ohms.

The samples demonstrate that a thicker printing of conductive material is required at the appointed bond locations to provide a bond-path having a sufficiently low resistance (and sufficiently high conductivity) through the thickness of the film that is interposed between the bonded circuit-paths. The bond energy, pressure, time and ultrasonic bonder style are highly variable and dependant on the substrates that contain the conductive components.

Those skilled in the art will recognize that the present invention is capable of many modifications and variations without departing from the scope thereof. Accordingly, the detailed description and examples set forth above are meant to be illustrative only and are not intended to limit, in any manner, the scope of the invention as set forth in the appended claims.

1. A method, comprising:
providing a first electrically-conductive circuit-path;
separately providing a second electrically-conductive circuit-path;
positioning a portion of the first circuit-path proximally adjacent a portion of the second circuit-path at a first predetermined bond location;
providing a first, electrically-insulating barrier layer interposed between the first circuit-path and second circuit-path at the first bond location; and
mechanically bonding the first circuit-path to the second circuit-path at the first bond location;
the mechanical bonding configured to provide an electrically-conductive bond-path between the first circuit-path and the second circuit-path at the first bond location.

2. A method as recited in claim 1, wherein
the mechanical bonding includes ultrasonic bonding;
the first electrically-conductive circuit-path has been applied to a first substrate which is substantially nonconductive to electrical currents; and
the first substrate has been configured to provide the first, electrically-insulating barrier layer.

3. A method as recited in claim 2, wherein the first electrically-conductive circuit-path has been applied by printing a first electrically-conductive material from a liquid-state of the first electrically-conductive material.

4. A method as recited in claim 2, wherein the first substrate has been provided by a first substrate material having a softening point temperature of up to about 150° C.

5. A method as recited in claim 2, wherein the first substrate has been provided by a first, film or nonwoven fabric material having a softening point temperature of up to about 150° C.

6. A method as recited in claim 2, wherein the first substrate has been provided by a first, film or nonwoven fabric material having a softening point temperature of up to about 150° C. and a flexibility value of up to about 0.03 gf*cm²/cm.

7. A method as recited in claim 2, wherein the second, separately provided electrically-conductive circuit-path has been applied to a second substrate which is substantially nonconductive to electrical currents.

8. A method as recited in claim 7, wherein second electrically-conductive circuit-path has been applied by printing a second electrically-conductive material from a liquid-state of the second electrically-conductive material.

9. A method as recited in claim 7, wherein the second substrate has been provided by a second film or nonwoven fabric material having a softening point temperature of up to about 150° C.

10. A method as recited in claim 7, wherein the first substrate has been provided by a first film or nonwoven fabric material having a softening point temperature of up to about 150° C. and a flexibility value of up to about 0.03 gf*cm²/cm.

11. A method as recited in claim 1, wherein
the first electrically-conductive circuit-path has been operatively connected to a sensor mechanism which provides sensor data; and
the second electrically-conductive circuit-path has been operatively connected to an electronic processor mechanism which receives the sensor data and provides signal data.

12. A method as recited in claim 1, wherein the bond-path has a resistance value which is not more than about 1 KΩ between the first circuit-path and second circuit-path.

13. A method as recited in claim 1, wherein the bond location has been bonded with a mechanism having percent bond area which is at least about 5% and up to about 60%.

14. A method as recited in claim 1, wherein conductive materials in at least portions of the circuit-paths located at the first bond location have a combined thickness, prior to bonding, which is at least about 5% of the thickness of the barrier layer that is interposed between the first and second circuit-paths.

15. A method as recited in claim 1, wherein the first electrically-conductive circuit-path has a resistivity value of not more than about 1 KΩ/m.

16. A method as recited in claim 1, wherein the first electrically-conductive circuit-path has a resistivity value of not more than about 100 Ω/m.

17. A method as recited in claim 1, wherein the first bond location has been configured to provide a bond shear-strength which is at least about 10% of a tensile strength of the barrier layer.

18. A method as recited in claim 1, wherein the bond location has a bond area of at least about 3.5 mm².

19. A method as recited in claim 1, wherein the first bond location has been configured to be substantially liquid-impermeable.

20. A method as recited in claim 1, wherein
the first electrically-conductive circuit-path has been applied to a first substrate which is substantially nonconductive to electrical currents;
the first substrate has been configured to provide the first, electrically-insulating barrier layer
the first electrically-conductive circuit-path has been applied to the first substrate by printing a first electrically-conductive material from a liquid-state of the first electrically-conductive material;
the first substrate has been provided by a first substrate material having a softening point temperature of up to about 150° C., and a flexibility value of up to about 0.03 gf*cm²/cm.
the mechanical bonding to provide an electrically-conductive bond-path between the first circuit-path and the second circuit-path at the first bond location has been provided by ultrasonically bonding the first circuit-path to the second circuit-path at the first bond location;
the first electrically-conductive circuit-path has a resistivity of not more than about 100 Ω/m;
the first bond location has been configured to provide a bond shear-strength which is at least about 10% of a tensile strength of the barrier layer;
the first bond-path has a resistance value of not more than about 1 KΩ between the first circuit-path and second circuit-path;
the first bond location is substantially liquid-impermeable.
